(19) United States
(12) Patent Application Publication
(10) Pub. No.: US 2018/0163548 A1
(43) Pub. Date: Jun. 14, 2018

(54) SELECTIVE THERMAL BARRIER COATING REPAIR

(71) Applicant: GENERAL ELECTRIC COMPANY, Schenectady, NY (US)

(72) Inventors: Dheepa SRINIVASAN, Bangalore (IN); James Ryan CONNOR, Greenville, SC (US); Joydeep PAL, Bangalore (IN)

(21) Appl. No.: 15/377,304

(22) Filed: Dec. 13, 2016

(51) Int. Cl. F01D 5/28; C23C 4/134; C23C 4/129; C23C 4/01; C23C 4/11; C23C 14/04; C23C 14/08; C23C 14/34; C23C 14/30; C23C 24/04; F01D 9/04; F01D 9/02; F01D 11/00; F23R 3/00; F02C 7/22

(52) U.S. Cl. CPC F01D 5/288; F05D 2300/171; C23C 4/129; C23C 4/01; C23C 4/11; C23C 14/04; C23C 14/081; C23C 14/083; C23C 14/34; C23C 14/30; C23C 24/04; F01D 9/041; F01D 9/023; F01D 11/005; F23R 3/002; F02C 7/222; F05D 2220/32; F05D 2240/35; F05D 2230/313; F05D 2230/312; F05D 2300/177; C23C 4/134

(57) ABSTRACT

A method of selectively applying an overlay coating to a coated article and a selectively treated coated article are provided. The method includes the steps of providing the coated article having a treatment region that includes a bond coat and a thermal barrier coating and selectively applying an overlay coating to the treatment region without stripping the treatment region from the coated article. The bond coat of the coated article which has been exposed to an operational temperature includes a first volume fraction of a β-phase microstructure that is less than a second volume fraction of a β-phase microstructure of a comparable bond coat of a comparable article which has not been exposed to the operational temperature. A coated article including an overlay coating selectively applied over a treatment region is also disclosed.

### FIELD OF THE INVENTION

The present invention is generally directed to a method for treating a coated article and a treated coated article. More specifically, the present invention is directed to a method of selectively applying an overlay coating to a coated article and a selectively treated coated article.

### BACKGROUND OF THE INVENTION

Gas turbines include components, such as buckets (blades), nozzles (vanes), combustors, shrouds, and other hot gas path components which are coated to protect the components from the extreme temperatures, chemical environments and physical conditions found within the gas turbines. Different coating systems may be applied to different locations of the same turbine components to meet the local conditions which vary across the turbine components.

In certain hot locations in the gas turbine, such as the blade tip or the trailing edge of the nozzle, the bond coat has reduced bond coat life (e.g. 20% or less that of the bulk component) as compared to the bulk of the component and will need replenishment before proceeding for another interval. In some instances, the bond coat service life is 20% or less that of the bulk of the component. The MCrAlY bond coat typically contains a two-phase microstructure β+γ, and high temperature operation results in depletion of Al both to the thermally grown oxide and to the substrate by interdiffusion, which leads to the dissolution or depletion of a β-phase microstructure. The bond coat life can be determined from the degree of β-phase microstructure depletion.

Typically, to refurbish the coating system when the bond coat life has been reached, a bond coat, as well as thermal barrier coating, is completely or partially striped and recoated to extend the coating life. The stripping and recoating operations, however, are time-consuming and do not result in an economical repair process.

### BRIEF SUMMARY OF THE INVENTION

In an exemplary embodiment, a method for treating a coated article is provided. The method includes the step of providing the coated article having a treatment region having a bond coat and a thermal barrier coating. The coated article has been exposed to an operational temperature. The method further includes the step of selectively applying an overlay coating to the treatment region without stripping the treatment region from the coated article. The overlay coating enables coating life extension of the coated article. The bond coat includes a first volume fraction of a β-phase microstructure that is less than a second volume fraction of a β-phase microstructure of a comparable bond coat of a comparable article which has not been exposed to the operational temperature.

In another exemplary embodiment, a treated coated article having a treatment region and an overlay coating is provided. The treated coated article has been exposed to an operational temperature. The treatment region includes bond coat and a thermal barrier coating. The bond coat includes a first volume fraction of a β-phase microstructure that is less than a second volume fraction of a β-phase microstructure of a comparable bond coat of a comparable article which has not been exposed to an operational temperature. The overlay coating is selectively applied over the treatment region without stripping the treatment region from the coated article, enabling coating life extension of the treated coated article.

Other features and advantages of the present invention will be apparent from the following more detailed description of the preferred embodiment which illustrates, by way of example, the principles of the invention.

### BRIEF DESCRIPTION OF THE DRAWINGS

FIG. 1 shows a flow chart diagram illustrating an embodiment of a method, according to an exemplary embodiment of the present disclosure.

FIG. 2 shows a side view of a turbine blade according to an embodiment of the present disclosure.

FIG. 3 schematically illustrates a method according to an embodiment of the present disclosure.

Wherever possible, the same reference numbers will be used throughout the drawings to represent the same parts.

### DETAILED DESCRIPTION OF THE INVENTION

The detailed description set forth below in connection with the appended drawings where like numerals reference like elements is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

All numbers expressing quantities of ingredients and/or reaction conditions are to be understood as being modified in all instances by the term “about”, unless otherwise indicated.

All percentages and ratios are calculated by weight unless otherwise indicated. All percentages are calculated based on the total weight of a composition unless otherwise indicated. All component or composition levels are in reference to the active level of that component or composition, and are exclusive of impurities, for example, residual solvents or by-products, which may be present in commercially available sources.

The articles “a” and “an,” as used herein, mean one or more when applied to any feature in embodiments of the present invention described in the specification and claims. The use of “a” and “an” does not limit the meaning to a single feature unless such a limit is specifically stated. The article “the” preceding singular or plural nouns or noun phrases denotes a particular specified feature or particular specified features and may have a singular or plural connotation depending upon the context in which it is used. The adjective “any” means one, some, or all indiscriminately of whatever quantity.

The term “at least one,” as used herein, means one or more and thus includes individual components as well as mixtures/combinations.

The term “comprising” (and its grammatical variations), as used herein, is used in the inclusive sense of “having” or “including” and not in the exclusive sense of “consisting only of.”

The term “overlay” (and its grammatical variations), as used herein, is a generic term covering all processes for application of the coating.

The present invention enables life extension of the coating without having to strip and recoat, enables a practical and simple method of reusing the external coating, enables a cost effective repair without additional steps involved, enables a faster turnaround time for repair, and enables fewer process steps in the repair router.

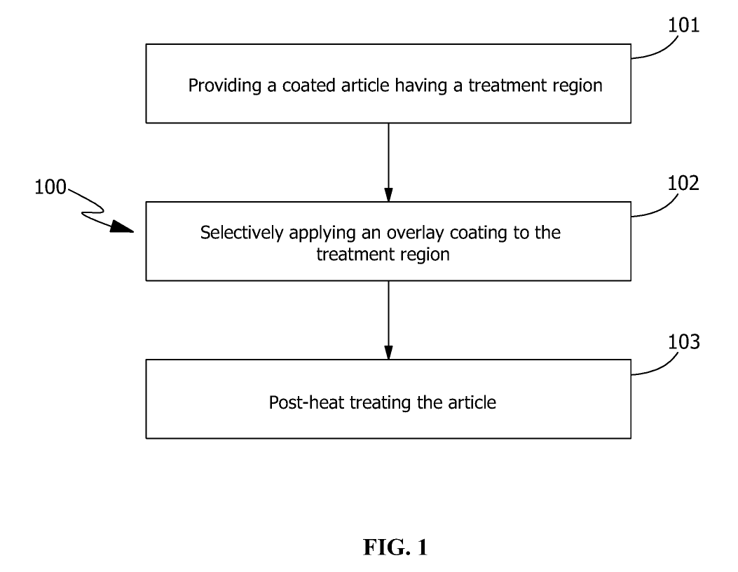

Referring to FIG. 1, a method 100 for treating a coated article having been exposed to an operational temperature may be provided. In one embodiment, the method includes the step of providing the coated article having a treatment region (step 101). The method also includes the step of selectively applying an overlay coating to the treatment region without stripping the treatment region from the coated article (step 102). The overlay coating enables coating life extension of the coated article. The treatment region may include a bond coat and/or a thermal barrier coating. The bond coat may have a first volume fraction of a β-phase microstructure that is less than a second volume fraction of a β-phase microstructure of a comparable bond coat of a comparable article which has not been exposed to the operational temperature. The bond coat may have a first volume fraction of a β-phase microstructure, which is at least 20 vol %. The comparable bond coat includes a bond coat that is greater than 20 vol % and has experienced little or no β-phase microstructure depletion. The bond coat prior to depletion and the comparable bond coat may include, but is not limited to a diffusion aluminide and/or a thermal sprayed overlay coating. Suitable bond coats may be applied, for example, by any known aluminide coating processes such as gel coating, slurry coating, vapor phase aluminization, above the pack process, EBPVD, and thermal spray processes such as HVOF (high velocity oxy-fuel), and air plasma spray (APS).

Method 100 further includes a post-heat treatment (step 103). The post-heat treatment enables diffusion of the overlay coating with the beta depleted bond coat. The post-heat treatment restores or rejuvenates the bond coat to some extent. The post-heat treatment may be provided via either high temperature operation or separate heat-treatment in a furnace.

The first volume fraction of the β-phase microstructure may be reduced or depleted by at least about 20% relative to the second volume fraction of the β-phase microstructure of the comparable bond coat. Preferably, the first volume fraction of the β-phase microstructure may be reduced by between about 20% and about 80%, about 20% and about 70%, about 20% and about 60%, about 20% and about 50%, about 20% and about 40%, about 20% and about 30%, about 30% and about 70%, about 30% and about 60%, about 30% and about 50%, about 30% and about 40%, about 40% and about 60%, or about 40% and about 50% relative to the second volume fraction of the β-phase microstructure of the comparable bond coat. Thus, in various embodiments, the first volume fraction of the β-phase microstructure may be reduced by from about 20 to about 80%, from 21 to about 79%, from about 22 to about 78%, from about 23 to about 77%, from about 24 to about 76%, from about 25 to about 75%, from about 26 to about 74%, from about 27 to about 73%, from about 28 to about 72%, from about 29 to about 71%, from about 30 to about 70%, from about 31 to about 69%, from about 32 to about 68%, from about 33 to about 67%, from about 34 to about 66%, from about 35 to about 65%, from about 36 to about 64%, from about 37 to about 63%, from about 38 to about 62%, from about 39 to about 61%, from about 40 to about 60%, from about 41 to about 59%, from about 42 to about 58%, from about 43 to about 57%, from about 44 to about 56%, from about 45 to about 55%, from about 46 to about 54%, from about 47 to about 53%, from about 48 to about 52%, from about 49 to about 51%, including increments and intervals therein, relative to the second volume fraction of the β-phase microstructure of the comparable bond coat.

The overlay coating may include the step of applying a material selected from the group consisting of yttria-stabilized zirconia, mullite, alumina, ceria, rare-earth zirconates, rare earth oxides, metal-glass composites, and combinations thereof. The overlay coating material may further include 7YSZ, 14YSZ, 2Y₂₀CeSZ, 25CeSZ, 5CaYSZ, 18Ca₂YSZ, (Gd,Yb)(Nd,Y)SZ, (Ti)YSZ, Al₂O₃—YSZ, Mullite-YSZ, (La)YSZ, Hf(YSZ), (Sm)YSZ, CaZrO₃, SrZrO₃, BaZrO₃, LaPO₄, MgAl₂O₄, LaMgAl₁₁O₁₉, Gd₂Zr₂O₇, Nd₂Zr₂O₇, Sm₂Zr₂O₇, La₂Zr₂O₇, Y₃Al₅O₁₂, La₂Mo₂O₉, BaY₂O₄, SrY₂O₄, SrCeO₃, BSAS, La₂Ce₂O₇, and combinations thereof. The overlay coating preferably may have a low thermal conductivity in order to provide great thermal protection.

The overlay coating may be selectively applied to a local portion of the coated article. The local portion may be less than an entire surface of the coated article.

In some embodiments, the method may include the step of commencing a servicing period of the coated article during which operation of the coated article. The apparatus may include the coated article. The method may be performed without stripping the bond coat from the coated article during the servicing period. The method may be performed without applying an additional bond coat to the coated article during the servicing period. The method may be performed without stripping the thermal barrier coating from the coated article during the servicing period.

In other embodiments, the overlay coating may include, but not limited to, a technique selected from the group consisting of spray processes, plasma spray, air plasma spray, high-velocity oxy-fuel (HVOF) spray, high-velocity air-fuel (HVAF) spray, high-velocity air plasma (HV-AP) spray, direct vapor deposition, electron beam physical vapor deposition, sol-gel process, cold-spray, sputtering, gel aluminide and combinations thereof.

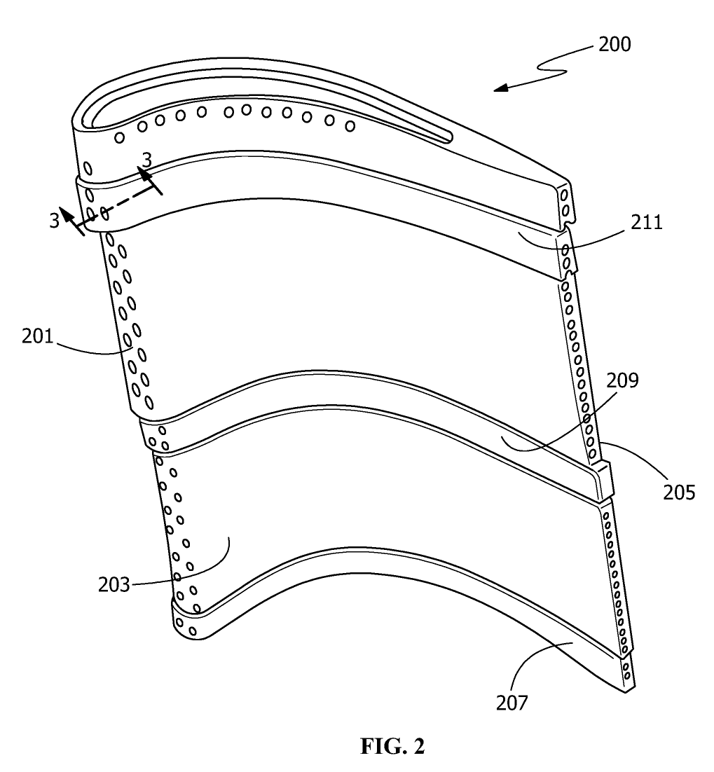

Referring to FIG. 2, the coated article 200 may be a turbine component. The turbine component may be selected from the group consisting of at least one of hot gas path components, combustion components, blades (buckets), vanes (nozzles), shrouds, combustor liners, transition ducts, cross fire tube collars, venturis, transition piece seals, and fuel nozzle parts. FIG. 2 shows a blade having a leading edge (201), a mid-portion (203), and a trailing edge (205) from left to right. The blade also includes a 10% span (207), a 50% span (209), and a 90% span (211) from bottom (0%) to top (100%).

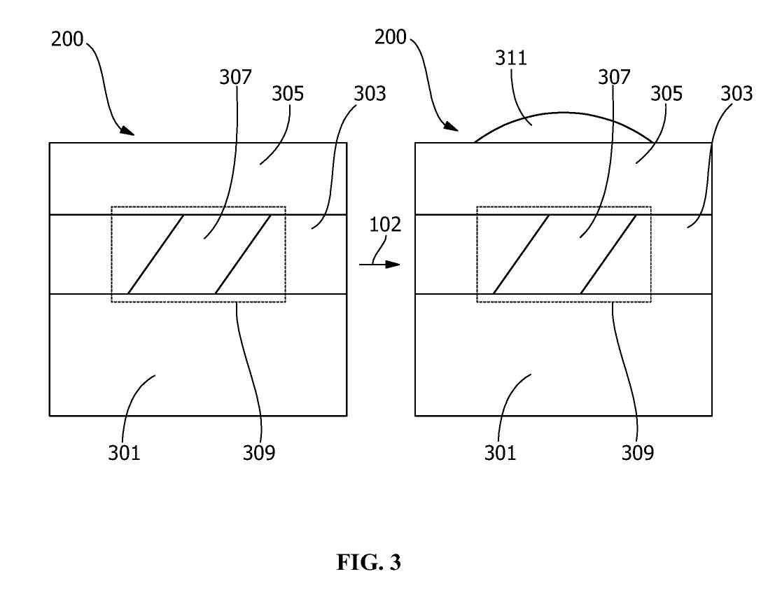

Referring to FIG. 3 and FIG. 1, the method 100 according to an embodiment according to the present disclosure is shown with a cross-section view from FIG. 2 shown in direction 3-3. The coated article 200 comprises a substrate 301, a bond coat 303, and a thermal barrier coating 305. The bond coat 303 may include, but is not limited to, a MCrAlY, wherein M is selected from the group consisting of nickel, cobalt, iron, alloys thereof, and combinations thereof. The thermal barrier coating 305 may include, but is not limited to materials selected from the group consisting of at least one of porous coatings, dense coatings, and dense vertically-cracked coatings. A portion of the coated article 200 which has been exposed to high temperature includes a depleted bond coat portion 307, which may include, but is not limited to, a β-phase microstructure dissolution and/or depletion that occurs in the treatment region 309 having the bond coat 303 and the thermal barrier coating 305. As shown in FIG. 3, the method according to the present disclosure includes selectively applying an overlay coating 311 over the treatment region 309 on, above, adjacent and/or encompassing the depleted bond coat portion 307 without stripping the treatment region 309 from the coated article 200 (step 102). The overlay coating 311 enables coating life extension of the coated article 200.

For example, in one embodiment, a certain portion of the coated article 200 exposed to high temperature, including the trailing edge portion 205 and/or the leading edge 201, may include only 45-55% of a remaining β-phase microstructure, which indicates that 45-55% of a β-phase microstructure may have been depleted during high temperature operation. Other locations on the coated article 200 suitable for the method according to the present disclosure includes, but is not limited to platform fillets and blade tips.

Method 100 further includes a post-heat treatment (step 103). The post-heat treatment enables diffusion of the overlay coating 311 with the beta depleted bond coat 303. The post-heat treatment restores or rejuvenates the bond coat 303 to some extent to enable it to serve another service interval.

In another embodiment, a treated coated article 200 may be provided. The treated coated article 200 may include, but not be limited to, a treatment region 309 having a bond coat 303 and a thermal barrier coating 305. The bond coat 303 may have a first volume fraction of a β-phase microstructure that is less than a second volume fraction of a β-phase microstructure of a comparable bond coat of a comparable article which has not been exposed to the operational temperature. The treated coated article 200 further may include an overlay coating 311 selectively applied over the treatment region.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for treating a coated article, the method comprising:
providing the coated article having a treatment region having a bond coat and a thermal barrier coating, the coated article having been exposed to an operational temperature; and
selectively applying an overlay coating to the treatment region without stripping the treatment region from the coated article, the overlay coating enabling coating life extension of the coated article,
wherein the bond coat having a first volume fraction of a β-phase microstructure that is less than a second volume fraction of a β-phase microstructure of a comparable bond coat of a comparable article which has not been exposed to the operational temperature.

2. The method of claim 1, wherein the bond coat is a MCrAlY, M being selected from the group consisting of nickel, cobalt, iron, alloys thereof, and combinations thereof.

3. The method of claim 1, wherein the first volume fraction of the β-phase microstructure is reduced by between about 20% and about 80% relative to the second volume fraction of the β-phase microstructure of the comparable bond coat.

4. The method of claim 1, wherein applying the overlay coating includes applying a material selected from the group consisting of yttria-stabilized zirconia, mullite, alumina, ceria, rare-earth zirconates, rare earth oxides, metal-glass composites, and combinations thereof.

5. The method of claim 1, wherein the overlay coating is applied to a local portion of the coated article, the local portion being less than an entire surface of the coated article.

6. The method of claim 1, including commencing a servicing period of the coated article during which operation of the coated article ceases.

7. The method of claim 1, wherein the method is performed without applying an additional bond coat to the coated article during the servicing period.

8. The method of claim 1, wherein applying the overlay coating includes a technique selected from the group consisting of spray processes, plasma spray, air plasma spray, high-velocity oxy-fuel (HVOF) spray, high-velocity air-fuel (HVAF) spray, high-velocity air plasma (HV-AP) spray, direct vapor deposition, electron beam physical vapor deposition, sol-gel process, cold-spray, sputtering, gel aluminide, and combinations thereof.

9. The method of claim 1, wherein the thermal barrier coating is selected from the group consisting of at least one of porous coatings, dense coatings, and dense vertically-cracked coatings.

10. The method of claim 1, wherein the coated article is a turbine component selected from the group consisting of at least one of hot gas path components, combustion components, blades (buckets), vanes (nozzles), shrouds, combustor liners, transition ducts, cross fire tube collars, venturis, transition piece seals, and fuel nozzle parts.

11. The method of claim 1, including a post-heat treatment after the selectively applying the overlay coating.

12. A treated coated article having been exposed to an operational temperature comprising:
a bond coat comprising a first bond coat region having a first volume fraction of a β-phase microstructure and a second bond coat region having a second volume fraction of a β-phase microstructure, the first volume fraction of a β-phase microstructure is less than the second volume fraction of a β-phase microstructure;
a treatment region having the first bond coat region and a thermal barrier coating; and
an overlay coating selectively applied over the first bond coat region without stripping the treatment region, the overlay coating enabling coating life extension of the treated coated article,
wherein the overlay coating is separated from the bond coat by the thermal barrier coating exposed to ambient temperature.

13. The treated coated article of claim 12, wherein the bond coat is a MCrAlY, M being selected from the group consisting of nickel, cobalt, iron, alloys thereof, and combinations thereof.

14. (canceled)

15. The treated coated article of claim 12, wherein the overlay coating includes a material selected from the group consisting of yttria-stabilized zirconia, mullite, alumina, ceria, rare-earth zirconates, rare earth oxides, metal-glass composites, and combinations thereof.

16. The treated coated article of claim 12, wherein the overlay coating is applied to a local portion of the coated article, the local portion being less than an entire surface of the coated article.

17. The treated coated article of claim 12, wherein the overlay coating is selectively applied over the first bond coat region without applying an additional bond coat to the coated article.

18. The treated coated article of claim 12, wherein the thermal barrier coating is selected from the group consisting of at least one of porous coatings, dense coatings, and dense vertically-cracked coatings.

19. The treated coated article of claim 12, wherein the treated article is a turbine component selected from the group consisting of hot gas path components, combustion components, blades (buckets), vanes (nozzles), shrouds, combustor liners, transition ducts, cross fire tube collars, venturis, transition piece seals, and fuel nozzle parts.

20. The treated coated article of claim 12, wherein the treated article is post-heat treated.

21. The treated coated article of claim 12, wherein the treated coated article is a hot gas path component.

22. The treated coated article of claim 12, wherein the overlay coating and thermal barrier coating provide greater thermal protection to the first bond coat region than the overlay coating and thermal barrier coating provide to the second bond coat region.

23. The treated coated article of claim 12, wherein the overlay coating and thermal barrier coating have greater thickness over the first bond coat region than the overlay coating and thermal barrier coating have over the second bond coat region.

24. The treated coated article of claim 12, wherein the thermal barrier coating is coextensive with the first bond coat region.
